(19) United States
(12) Patent Application Publication
(10) Pub. No.: US 2026/0013076 A1
(43) Pub. Date: Jan. 8, 2026

(54) COOLING DEVICE, AND MOTOR VEHICLE WITH A COOLING DEVICE

(71) Applicant: AUDI AG, lngolstadt (DE)

(72) Inventor: Klaus MEIERLING, Bochum (DE)

(73) Assignee: AUDI AG, lngolstadt (DE)

(21) Appl. No.: 19/254,749

(22) Filed: Jun. 30, 2025

(30) Foreign Application Priority Data
Jul. 2, 2024 (DE) 102024118779.4

(51) Int. Cl. H05K 7/20

(52) U.S. Cl. CPC H05K 7/20272; H05K 7/20263

(57) ABSTRACT

A cooling device including a cooling element designed as a bag for a coolant, and a heat dissipation element arranged on the cooling element and a motor vehicle with an embodiment of the cooling device. The heat dissipation element can be designed as a frame element for the cooling element, and the frame element can preferably have at least one groove on its longitudinal side. Additionally or alternatively, the heat dissipation element can be designed as a Peltier element, and the heat dissipation element can form an outer wall of the cooling element.

### FIELD

The invention relates to a cooling device, in particular a cooling device for a component of a motor vehicle, for example for cooling a control unit of a motor vehicle. Furthermore, the invention also relates to a motor vehicle having a cooling device.

### BACKGROUND

Today, more and more control units are being installed in vehicles which, due to high power losses, heat up to such an extent that the electronic components would be destroyed if the surfaces of the housings were not actively cooled.

In the area of water-cooled cooling plates, deep-drawn metal sheets are often welded together; the water then flows through the profile and transports with it the heat absorbed from the metal sheets. A new variant is to replace the deep-drawn metal sheets with a “water bag” made of a temperature-resistant and thermally conductive material.

US 2023/0059778 B2 relates to an aerospace battery comprising a housing, a retaining seat arranged in the housing and a battery pack core supported by the retaining seat in the housing. Optional cooling plates may include features that help isolate heat within regions of the cooling plate. For example, the cooling plate may comprise a flexible bag defining at least one liquid cooling channel.

US 2023/020052 A1 describes an efficient and environmentally friendly method for the selective extraction of lithium from secondary lithium-ion batteries of any capacity and size at the end of their service life. A temperature was achieved by placing the bag cell in a Peltier cooling platform.

DE 10 2011 082204 A1 describes a thermoelectric unit with an inner fluid guide element which has a plurality of outer surfaces and in which a plurality of fluid channels are arranged.

Cooling plates have the task of dissipating the heat from the control units as efficiently as possible. Each material has its own thermal resistance. The thicker the material, the greater the resistance. Air has very poor thermal resistance, so a cooling plate must have as large a contact surface as possible with the control unit without any air pockets. For this reason, a thermal interface material (TIM material) in the form of putty is often used, which causes additional costs and also problems during installation, in order to improve the contact surface between the cooling plate and the control unit and to avoid air pockets. However, this also increases the thermal resistance. Further disadvantages of such thermally conductive putty are that it becomes soft over time, which is why the holding forces decrease. Screws can come loose, making the construction even more unstable.

Usually there are not many mounting options for a cooling plate, except in the edge regions, since the control units do not allow any additional screwing options in the central surface region. This facilitates the cooling plate to bulge from the surface.

Alternatively, the surface of the contact surface of the cooling plate can be cambered in order to achieve a flat contact pressure, which also causes additional costs for the manufacturer. A cambering of the cooling plate could solve the problems of the thermally conductive putty, but it increases the cost of production and can cause further problems with tolerances in the screw connection.

A prior art solution using a water bag for cooling solves some of these problems. The material is very thin compared to the metal sheets and it can cling to an uneven surface. Such a solution can be easily installed in a control unit, for example between the circuit board and the housing base. However, problems could arise when screwing the housing to the outer surfaces if there is no contact surface opposite the control unit surface to be cooled.

FIG. 1 shows a diagram of a common solution principle from the prior art, wherein a device to be cooled, for example a control unit 1, is cooled with a cooling plate 2. Thus, two hard surfaces are pressed against each other. The contact area depends on the roughness and flatness of the surface. Dirt particles and air pockets can separate the contact surfaces from each other over large areas.

FIG. 2 shows a solution principle from the prior art in which a bag 3, which can also be referred to as a “water bag” or “pouch cell”, presses against the surface of the control unit 1. Such a “water bag” fits much better to the surface than a “solid” cooling plate 2. Dirt particles are trapped and do not have a major impact on the contact surface.

FIG. 3 shows a solution principle from the prior art, in which a housing of the exemplary control unit 1 has recesses on the side to be cooled. If the surface to be cooled has structural unevenness or depressions, both variants from FIG. 1 and FIG. 2 have disadvantages, because the bag 3 does not compensate for the unevenness or depressions.

### SUMMARY

One object of the invention is to increase the efficiency of cooling of devices to be cooled, for example apparatuses. The stated object is achieved by a cooling device according to the invention and a motor vehicle according to the invention according to the independent claims. Advantageous developments are specified by the dependent claims.

The invention is based on the idea of providing a cooling device that combines a cooling element designed as a bag with a heat dissipation element. The design as a bag means that the cooling element has a volume into which a coolant can be filled and stored, and the outer wall of which is easily deformable. In other words, the cooling element is hollow and easily deformable and is suitable for accommodating the coolant. An outer wall of the cooling element and thus its shape is therefore flexible. The outer wall of the cooling element can, for example, be made of an elastic material and/or, for example, be designed as a film or a deformable plastic. A coolant is a cooling means, for example water, liquid metals, oil or alcohol. In other words, the cooling means is a gaseous, liquid or solid substance or a mixture of substances that is used to remove heat and conducts the heat to a heat sink. In other words, the cooling element is to be understood as a component that cools with the help of the coolant.

The cooling device according to the invention accordingly has a cooling element designed as a bag for a coolant, and a heat dissipation element arranged on the cooling element. Preferably, the cooling device may also comprise the coolant. A heat dissipation element is understood to be a component or a group of components that transfers heat between the device to be cooled, for example a control unit of a motor vehicle, to the cooling element of the cooling device. Suitable materials for the heat dissipation element include metals, for example.

The motor vehicle according to the invention has an embodiment of the cooling device according to the invention, wherein the cooling device is arranged at least partially with its heat conducting element on a cooling side of the cooling element and on a device of the motor vehicle to be cooled.

The combination of cooling element and heat dissipation element achieves even more efficient heat dissipation from the device to be cooled to the cooling element. This also saves installation space and costs. The cooling element designed as a bag can be adapted much more precisely to the device to be cooled. The use of TIM material can be dispensed with, thus eliminating its disadvantages. The stability of a cooling device fixed in this way is therefore much better and more lasting. The heat dissipation element connects the cooling element to the device to be cooled.

In a preferred embodiment of the cooling device according to the invention, the cooling element can be designed as a hose. The use of a hose as a cooling element enables a very space-saving arrangement in, for example, a motor vehicle.

Preferably, the cooling element, in particular an outer wall of the cooling element, may comprise an electrocaloric material or consist of an electrocaloric material. Based on the principle of an electrocaloric heat pump, the heat can be dissipated in this way. This results in particularly efficient cooling. In contrast to a Peltier effect, cooling is possible regardless of the current level.

Additionally or alternatively, the cooling device may comprise an electrocaloric system. This results in particularly efficient cooling. Suitable systems, for example an electrocaloric heat pump, are known to the person skilled in the prior art.

In a particularly preferred embodiment of the cooling device according to the invention, the cooling element can form at least one nub on a cooling side. This means that an outer wall of the cooling element can form at least one nub. The cooling side of the cooling element is understood to be the side that, when installed, faces the device to be cooled. Preferably, the cooling side of the cooling element can be the one against which the heat dissipation element rests. By forming at least one nub, unevenness and depressions in the housing of the device to be cooled can be better compensated.

In a further particularly preferred embodiment, the heat dissipation element of the cooling device can be designed as a frame element for the cooling element. A frame element is understood to be a component that at least partially surrounds the cooling element and/or against which the cooling element at least partially rests. The frame element can preferably have at least one groove on its longitudinal side. The side of the cooling element which then rests against this longitudinal side of the frame element with the opposite side is then the cooling side. When installed, for example in a motor vehicle, the frame element then rests against the device to be cooled. This results in even more efficient heat dissipation from the device to be cooled.

The heat dissipation element is, when designed as a frame element, formed during manufacture to fit precisely or more precisely to a surface of the housing of a control unit to be cooled. The frame element can thus act as an adapter between the cooling element and the device to be cooled. This increases stability and makes cooling more efficient. This can also reduce air pockets. In addition, a heat dissipation element designed as a frame element has a significantly higher conductivity than thermally conductive putty.

In a corresponding embodiment of the motor vehicle according to the invention, which has a cooling device with a heat dissipation element designed as a frame element, the cooling element rests with its cooling side on the heat dissipation element designed as a frame element, the opposite longitudinal side of which is shaped such that the longitudinal side rests flatly on one side of the housing of the device of the motor vehicle to be cooled. The advantages have already been discussed above.

In a further development of the motor vehicle according to the invention, the at least one groove of the frame element engages in a recess of a housing of the device of the motor vehicle to be cooled. Due to the flexibility of the outer wall of the cooling element, the housing, frame element and cooling element are in direct contact with each other and the heat can be dissipated even more efficiently.

If the motor vehicle has an embodiment of the cooling device on the cooling side of which at least one nub is formed, the at least one nub engages in a recess of the housing and/or in a groove of the heat dissipation element. Here, too, heat is dissipated particularly efficiently.

In a further particularly preferred embodiment of the cooling device according to the invention, it has at least one spring element arranged on the cooling side of the cooling element. The spring element can, for example, be a part of the outer wall of the cooling element, or a separate component that can, for example, be formed from one or two bent metal strips. This allows the cooling element to adapt even more efficiently to unevenness and depressions in the device to be cooled. The spring element is a component or a region of a component that can have a springy effect when pressure is applied.

In an embodiment of the cooling device in which the heat dissipation element is designed as a frame element which has at least one groove on its longitudinal side, a bottom side of the at least one groove can preferably be designed as the spring element. This gives the structure greater stability than if the spring element is not part of the frame element.

In a further, particularly preferred embodiment of the cooling device according to the invention, the heat dissipation element can be designed as a Peltier element. The heat dissipation element can form an outer wall of the cooling element. The outer layer can then preferably be designed as an outer skin or outer wall of the cooling element. This allows cooling to be controlled, and the cooling device can be used to specifically regulate the temperature of the device to be cooled.

Depending on how the two materials of the Peltier element of the cooling element are supplied with current, heating or cooling can occur. Material combinations for displacement and heat transport are known to the skilled in the art.

The device to be cooled can be, for example, a motor vehicle battery, a rechargeable battery or a control unit. In particular, an embodiment of the cooling device with a Peltier element is useful for tempering a battery or accumulator, for example to reduce the risk of the battery or accumulator freezing at low outside temperatures.

A further advantage of the Peltier element design is that additional energy can be recovered via the Peltier element when the motor vehicle is already switched off but, for example, the control unit to be cooled is still hot.

In a preferred development, the cooling device can additionally have a spacer element which separates the cooling side of the cooling element from a side of the cooling element opposite the cooling side. The cooling element can here preferably be designed as a hose. An input load is thereby spaced from the output load via the spacer element in order to efficiently prevent a short circuit.

The motor vehicle according to the invention is preferably designed as an automobile, in particular as a passenger car or truck, or as a passenger bus or motorcycle. Optionally, the motor vehicle can be designed as an autonomous motor vehicle.

The invention also includes developments of the motor vehicle according to the invention, which have features as already described in the context of the developments of the cooling device according to the invention. For this reason, the corresponding developments of the motor vehicle according to the invention are not described again here.

The invention also comprises the combinations of the features of the described embodiments. The invention therefore also comprises implementations which each have a combination of the features of several of the described embodiments, unless the embodiments have been described as mutually exclusive.

### BRIEF DESCRIPTION OF THE FIGURES

Exemplary embodiments of the invention are described hereinafter. In the figures:

FIG. 1 shows a schematic representation of a cooling device from the prior art;

FIG. 2 shows a schematic representation of a further cooling device from the prior art;

FIG. 3 shows a schematic representation of a further cooling device from the prior art;

FIG. 4 shows a schematic representation of an exemplary embodiment of a cooling device according to the invention with a heat dissipation element designed as a frame element, and an exemplary embodiment of a motor vehicle according to the invention;

FIG. 5 shows a schematic representation of an exemplary embodiment of a spring element;

FIG. 6 shows a schematic representation of an exemplary embodiment of a cooling device according to the invention with a heat dissipation element designed as a Peltier element, and an exemplary embodiment of a motor vehicle according to the invention; and

FIG. 7 shows a schematic representation of a further exemplary embodiment of a cooling device according to the invention with a heat dissipation element designed as a Peltier element, and an exemplary embodiment of a motor vehicle according to the invention.

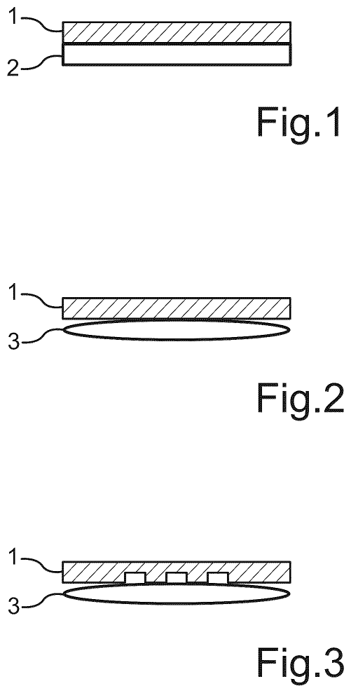

### DETAILED DESCRIPTION

The exemplary embodiments explained below are preferred embodiments of the invention. In the exemplary embodiments, the described components of the embodiments each represent individual features of the invention to be considered independently of one another, which each also develop the invention independently of one another. Therefore, the disclosure is also predetermined to comprise combinations of the features of the embodiments other than those represented. Furthermore, the described embodiments can also be supplemented by further ones of the above-described features of the invention.

In the figures, same reference numerals respectively designate elements that have the same function.

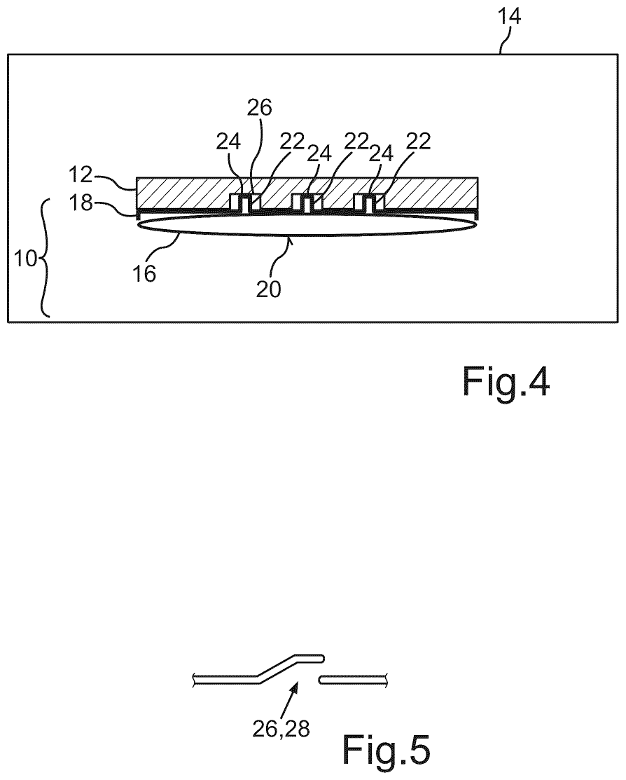

FIG. 4 shows a first exemplary embodiment of a cooling device 10 according to the invention, which can already be arranged for cooling on a device 12 to be cooled, for example a control unit. FIG. 4 also shows, in a highly schematic manner, an exemplary embodiment of an exemplary motor vehicle 14 in which the exemplary control unit with the cooling device 10 can be installed.

The motor vehicle 14 of FIG. 4 can be designed, for example, as a passenger car or a truck.

FIG. 4 shows the principle of the combination of a cooling element 16 designed as a bag and a heat dissipation element 18. In the example of FIG. 4, the heat dissipation element 18 is designed as a frame element. The cooling element 16 may, for example, be a bag containing water as a coolant, and an outer wall 20 of the cooling element 16 may, for example, consist of a soft plastic or comprise a soft plastic. In another embodiment other than that shown in FIG. 4, the cooling element 16 can be designed as a hose.

The heat dissipation element 18, designed as a frame element, is shaped in its longitudinal extent such that the longitudinal side lies flat against a part of the housing of the device 12 to be cooled, and can preferably be made of a heat-conducting material.

Due to the flexibility of the material of the outer wall 20, it is pressed into respective grooves 22 on the side facing the heat dissipation element 18. Alternatively, the outer wall 20 can form nubs at least on the cooling side, which can be shaped to match the grooves 22 of the heat dissipation element 18. The cooling element 16 can then be inserted into the heat dissipation element 18 with its grooves 22, and the heat dissipation element 18 can then be inserted with its grooves 22 into corresponding recesses 24 in the housing of the device 12 to be cooled. Preferably, the heat dissipation element 18 can be shaped on one longitudinal side to fit precisely or partially to the shape of the surface of the device 12 to be cooled.

In a design with nubs, for example as an alternative to spring elements, or as a combination with spring elements, these nubs can be designed as “air cushion nubs”, for example, but preferably each be a bulge of the outer wall 20, so that the coolant fills the nubs from the inside.

Preferably, a bottom side 26 of a groove 22 can be designed as a spring element 28. FIG. 5 shows an example of a preferred spring element 28 with, for example, two legs, so that the bottom side 26 can be interrupted, and one of the two legs can be bent twice. This double-bent leg then presses, in the installed state, either against the recess 24 of the device 12 to be cooled, or the double-bent leg can be aligned towards the outer wall 20 of the cooling element 16. A spring element 28 is understood to be a component that causes a resilient counterpressure when pressure is applied. The spring element 28 may preferably consist of, for example, aluminum or copper, or comprise aluminum or copper. For example, by completely or partially constructing the spring element 28 from aluminum, a heat dissipation of 120-130 watts per megakelvin can be achieved. The at least one spring element 28 may preferably consist of a heat-conducting material or comprise a heat-conducting material. In addition to the precise snuggling fit of the cooling element 16 to the frame element, i.e. the improved fit of the cooling element 16, a better dissipation of the heat in the recesses 24 is also achieved.

In an alternative embodiment, individual, separate spring elements 28 may form the heat dissipation element 18, wherein the individual spring elements 28 may or may not be connected to one another. In the latter embodiment, for example, multiple spring elements 28 can be mounted directly on the outer wall 20 of the cooling element 16. The attachment can be done by gluing, for example.

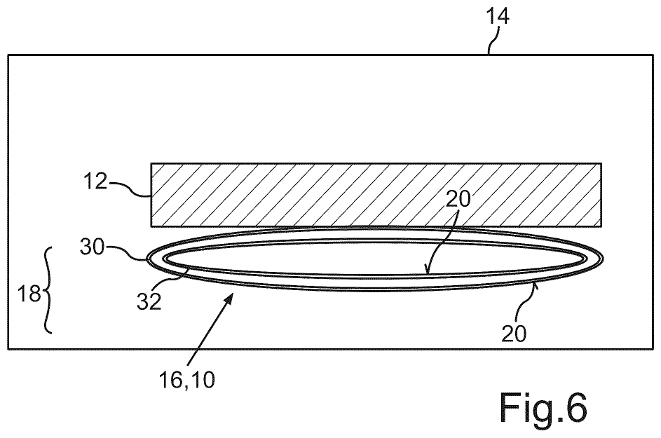

FIG. 6 shows an exemplary embodiment in which the heat dissipation element 18 is designed as a Peltier element and forms the outer wall 20 of the cooling element 16. In this example, the cooling element 16 can preferably be designed as a hose. The outer wall 20 can also be referred to as the outer skin. In the example of FIG. 6, the heat dissipation element 18 is shown as being integrated all around, but the heat dissipation element 18 can also be integrated only partially all around. The exemplary control unit may, for example, require a “comfort” temperature, i.e. an optimized and controlled temperature. Depending on the direction of the current supply to the Peltier element, heat can also be supplied to the control unit to be cooled.

The Peltier element can then form the heat dissipation element 18 by two different, for example separate material layers 30, 32. Suitable material combinations are known to the person skilled in the art. The advantage of using a Peltier element is also that the Peltier element can recover energy when the motor vehicle 14 is switched off but the exemplary control unit is still hot.

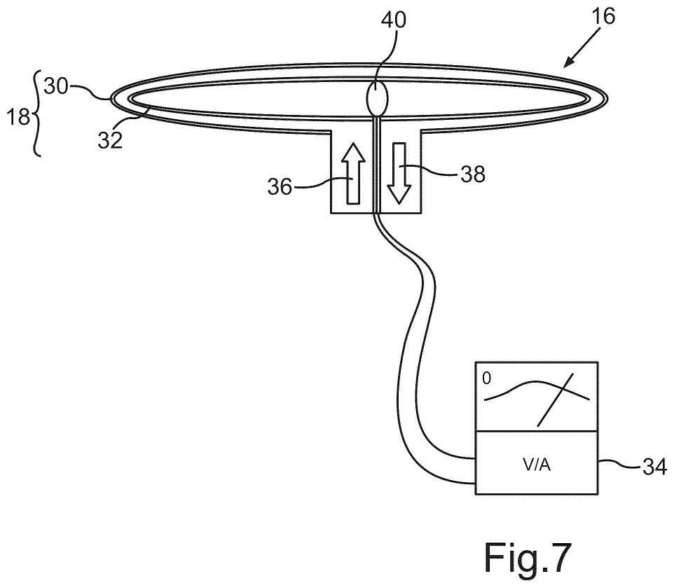

FIG. 7 shows an embodiment of a cooling element 16 with a Peltier element as heat dissipation element 18, in which a current source 34 is also shown. FIG. 7 shows an inflow direction 36 in which cold coolant flows in and an outflow direction 38 in which heated liquid flows out. When reversed, warm liquid can be introduced and cold liquid can flow out. The Peltier element, past which the water flows at different temperatures, generates a voltage and a current that can be measured. From this, the temperature and thus also the power of the cooling during operation can be read and derived.

FIG. 7 also shows a spacer element 40, i.e. a component with which the two opposite sides of the cooling element 16 are spaced apart. The spacer element may preferably consist of a non-heat-conducting material, for example a hard plastic.

Overall, the examples show how a cooling device, for example a smart cooling plate or smart hose cooling, can be provided.

In contrast to the previously known methods, optional designs with at least one spring element 28, which can be designed as a spring, for example, and/or with at least one nub ensure optimal contact of the cooling—i.e. the cooling element 16—with the housing to be cooled (FIG. 4).

A further preferred embodiment (FIG. 6) is based on a further development of a Peltier element. The advantages of integration into the cooling element 16 designed as a bag, which can also be referred to as a “pouch cell”, are A) even better cooling performance, because the heat is dissipated better/faster by applying a voltage, and B) the power of the “cooling cell” can be queried at any time by measuring the voltage generated. This is done much more accurately than any temperature sensor. It is not necessary to integrate the Peltier element structure all the way around. If the device to be cooled in the motor vehicle, for example a control unit, requires a “comfortable” temperature, heat can also be supplied to the control unit with reverse current supply.

The optional Peltier element is flown past by the cooling liquid, for example water, with the different temperatures and generates a voltage and a current that can be measured. From this, the temperature and thus also the power of the cooling during operation can be read and derived. (FIG. 7).

Overall, a faulty construction can be immediately identified in all exemplary embodiments. The performance can be adjusted at any time. Energy recovery is possible. Cooling power is improved, weight is saved, and all variants are cheaper to produce.

All embodiment variants reduce the required installation space and significantly increase the cooling efficiency.

1. A cooling device, comprising:
a cooling element designed as a bag for a coolant, and
a heat dissipation element arranged on the cooling element.

2. The cooling device according to claim 1, wherein the cooling element is designed as a hose.

3. The cooling device according to claim 1, wherein the cooling element forms at least one nub on a cooling side.

4. The cooling device according to claim 1, wherein the heat dissipation element is designed as a frame element for the cooling element; preferably wherein the frame element has at least one groove on its longitudinal side.

5. The cooling device according to claim 1, which has at least one spring element arranged on the cooling side of the cooling element.

6. The cooling device according to claim 4, wherein a bottom side of the at least one groove is designed as the spring element.

7. The cooling device according to claim 4, wherein the heat dissipation element is designed as a Peltier element, and wherein the heat dissipation element forms an outer wall of the cooling element.

8. The cooling device according to claim 7, comprising a spacer element which spaces the cooling side of the cooling element from a side of the cooling element opposite the cooling side; preferably wherein the cooling element is designed as a hose.

9. A motor vehicle with a cooling device according to claim 1, wherein the cooling device is arranged at least partially with its heat dissipation element on a cooling side of the cooling element and is arranged on a device of the motor vehicle to be cooled.

10. The motor vehicle with a cooling device according to claim 9, wherein the cooling element rests with its cooling side on the heat dissipation element designed as a frame element, the longitudinal side of which is shaped and arranged on the device to be cooled in such a way that the longitudinal side rests flatly on a side of a housing of the device to be cooled of the motor vehicle.

11. The motor vehicle according to claim 10, wherein the at least one groove of the frame element engages in a recess of a housing of the device to be cooled of the motor vehicle.

12. The motor vehicle according to claim 9, wherein the cooling element of the cooling device forms at least one nub on its cooling side, which nub is arranged on the cooling side in such a way that it engages in a recess of the housing and/or in a groove of the heat dissipation element.

13. The motor vehicle according to claim 9, wherein the device to be cooled is a control unit or a battery of the motor vehicle.

14. The cooling device according to claim 2, wherein the cooling element forms at least one nub on a cooling side.

15. The cooling device according to claim 2, wherein the heat dissipation element is designed as a frame element for the cooling element; preferably wherein the frame element has at least one groove on its longitudinal side.

16. The cooling device according to claim 3, wherein the heat dissipation element is designed as a frame element for the cooling element; preferably wherein the frame element has at least one groove on its longitudinal side.

17. The cooling device according to claim 2, which has at least one spring element arranged on the cooling side of the cooling element.

18. The cooling device according to claim 3, which has at least one spring element arranged on the cooling side of the cooling element.

19. The cooling device according to claim 4, which has at least one spring element arranged on the cooling side of the cooling element.

20. The cooling device according to claim 5, wherein a bottom side of the at least one groove is designed as the spring element.
